(19) United States
(12) Patent Application Publication
(10) Pub. No.: US 2025/0201561 A1
(43) Pub. Date: Jun. 19, 2025

(54) METHOD FOR MANUFACTURING SEMICONDUCTOR DEVICE AND PATTERN FORMING METHOD

(71) Applicant: Kioxia Corporation, Tokyo (JP)

(72) Inventor: Kazuhiro TAKAHATA, Yokohama (JP)

(73) Assignee: Kioxia Corporation, Tokyo (JP)

(21) Appl. No.: 18/830,312

(22) Filed: Sep. 10, 2024

(30) Foreign Application Priority Data
Dec. 19, 2023 (JP) 2023-213939

(51) Int. Cl. H01L 21/033

(52) U.S. Cl. CPC H01L 21/0337

(57) ABSTRACT

A first hole pattern is transferred to a first hard mask layer to form a first hard mask pattern having a second hole pattern, a first spacer layer is formed on a side wall of the second hole pattern and the first hard mask pattern is removed to form a first spacer pattern being cylindrical and arranged at a position of the second hole pattern, a second spacer layer covering an upper surface of the second hard mask layer outside the first spacer pattern is formed, and a second spacer pattern having a third hole pattern is formed by removing the second spacer layer overlapping a first region consisting of a minimum distance connecting center points of the first spacer pattern, to form a fourth hole pattern including the second hole pattern included in the first spacer pattern and the third hole pattern included in the second spacer pattern.

### CROSS-REFERENCE TO RELATED APPLICATIONS

This application is based upon and claims the benefit of priority from Japanese Patent Application No. 2023-213939, filed on Dec. 19, 2023; the entire contents of which are incorporated herein by reference.

### FIELD

Embodiments described herein relate generally to a method for manufacturing a semiconductor device and a pattern forming method.

### BACKGROUND

Along with miniaturization of semiconductor devices, there is an increasing demand for finely forming patterns such as holes. As a fine hole pattern, a hexagonal close-packed arrangement in which holes are arranged at vertexes of a regular hexagon and center points of the regular hexagon when viewed from above may be employed.

In order to form the hexagonal close-packed arrangement as described above at a pitch finer than a limit resolution of lithography while using a lithography technique, for example, a method called cross point processing has been proposed. However, in the cross point processing, there are many problems to be improved, such as a large number of processes and requiring time and effort for pattern alignment.

### BRIEF DESCRIPTION OF THE DRAWINGS

FIGS. 1A and 1B are views illustrating an example of a configuration of a semiconductor device according to an embodiment;

FIGS. 2A to 2C are schematic top views describing an outline of a method for manufacturing the semiconductor device according to the embodiment;

FIGS. 3Aa to 3Bb are views sequentially illustrating a part of the procedure of the method for manufacturing the semiconductor device according to the embodiment;

FIGS. 4Aa to 4Cb are views sequentially illustrating a part of the procedure of the method for manufacturing the semiconductor device according to the embodiment;

FIGS. 5Aa to 5Cb are views sequentially illustrating a part of the procedure of the method for manufacturing the semiconductor device according to the embodiment;

FIGS. 6Aa and 6Ab are views sequentially illustrating a part of the procedure of the method for manufacturing the semiconductor device according to the embodiment;

FIGS. 7Aa to 7Cb are views sequentially illustrating a part of the procedure of the method for manufacturing the semiconductor device according to the embodiment;

FIGS. 8Aa to 8Cb are views sequentially illustrating a part of the procedure of the method for manufacturing the semiconductor device according to the embodiment;

FIGS. 9Aa to 9Bb are views sequentially illustrating a part of the procedure of the method for manufacturing the semiconductor device according to the embodiment; and

FIGS. 10Aa to 10Cb are views sequentially illustrating a part of the procedure of the method for manufacturing the semiconductor device according to the embodiment.

### DETAILED DESCRIPTION

A method for manufacturing a semiconductor device according to an embodiment includes forming first and second hard mask layers above a layer to be processed in order of the second hard mask layer and the first hard mask layer from a side of the layer to be processed, forming a resist mask pattern having a first hole pattern formed using lithography above the first hard mask layer, transferring the first hole pattern to the first hard mask layer to form a first hard mask pattern having a second hole pattern, forming a first spacer layer on a side wall of the second hole pattern and removing the first hard mask pattern to form a first spacer pattern being cylindrical and arranged at a position of the second hole pattern, forming a second spacer layer at least covering an upper surface of the second hard mask layer outside the first spacer pattern, and partially removing the second spacer layer overlapping a first region consisting of a minimum distance connecting center points of the first spacer pattern to form a second spacer pattern having a third hole pattern, to form a fourth hole pattern including the first spacer pattern and the third hole pattern included in the second spacer pattern, transferring the fourth hole pattern to the second hard mask layer to form a second hard mask pattern having a fifth hole pattern, forming a third spacer layer on a side wall of the fifth hole pattern, and removing the second hard mask pattern to form a third spacer pattern being cylindrical and arranged at a position of the fifth hole pattern, forming a fourth spacer layer at least covering an upper surface of the layer to be processed outside the third spacer pattern, and partially removing the fourth spacer layer overlapping a second region consisting of a minimum distance connecting center points of the third spacer pattern to form a fourth spacer pattern having a sixth hole pattern, to form a seventh hole pattern including the third spacer pattern and the sixth hole pattern included in the fourth spacer pattern, and transferring the seventh hole pattern to the layer to be processed.

Hereinafter, embodiments of the present invention will be described in detail with reference to the drawings. Note that the present invention is not limited by the following embodiments. In addition, components in the following embodiments include those that can be easily assumed by those skilled in the art or those that are substantially identical.

### First Embodiment

Hereinafter, a first embodiment will be described in detail with reference to the drawings.

### (Configuration Example of Semiconductor Device)

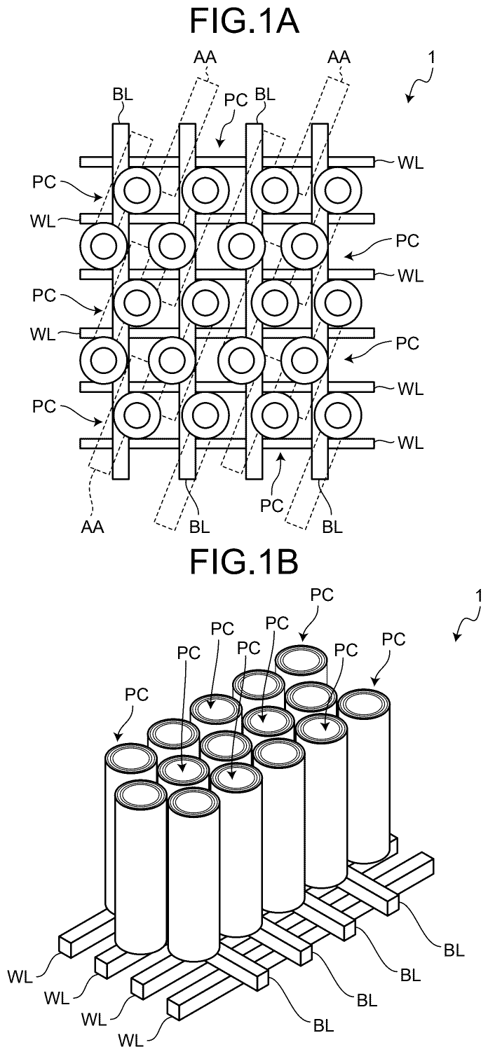

FIGS. 1A and 1B are views illustrating an example of a configuration of a semiconductor device 1 according to an embodiment. FIG. 1A is a top view of the semiconductor device 1 according to the embodiment, and FIG. 1B is a perspective view of the semiconductor device 1 according to the embodiment. The semiconductor device 1 according to the embodiment is configured as, for example, a dynamic random access memory (DRAM).

As illustrated in FIGS. 1A and 1B, the semiconductor device 1 includes a plurality of word lines WL separated from each other by a predetermined distance and extending in a predetermined direction, a plurality of bit lines BL separated from each other by a predetermined distance and extending on the word lines WL in a direction intersecting the word line WL, and a plurality of pillar capacitors PC arranged as many as intersections of the word lines WL and the bit lines BL on the bit lines BL. In addition, an active region AA in which a predetermined dopant is diffused is formed in a semiconductor substrate, which is not illustrated, below these configurations.

In the semiconductor device 1 of the embodiment, each of the pillar capacitors PC functions as a memory cell capable of holding data by accumulating charges. Therefore, the storage capacity of the semiconductor device 1 can be increased as the pitch between the pillar capacitors PC is reduced as much as possible and arranged them as dense as possible.

Therefore, in the semiconductor device 1, when viewed from above, the individual pillar capacitors PC are arranged, for example, at each vertex of the regular hexagon and at the center point of the regular hexagon. By employing such an arrangement, the pillar capacitors PC can be densely arranged. Such an arrangement of the pillar capacitors PC is hereinafter referred to as a hexagonal close-packed arrangement following a hexagonal close-packed structure of a crystal structure.

### (Method of Manufacturing Semiconductor Device)

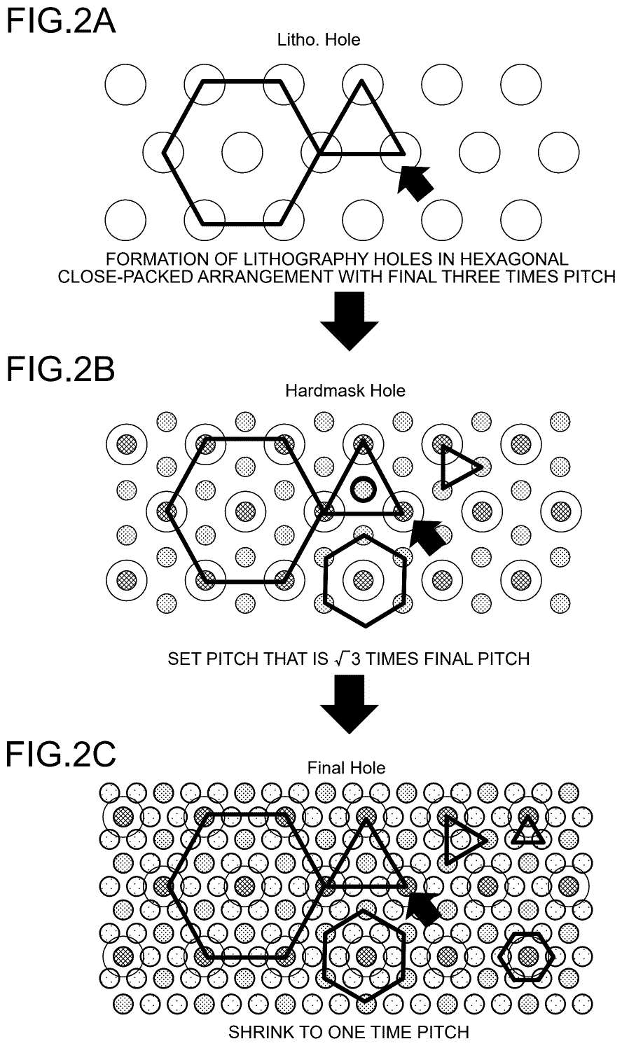

Next, a method for manufacturing the semiconductor device 1 according to the embodiment will be described with reference to FIGS. 2A to 10Cb.

In the semiconductor device 1 of the embodiment, in order to form the pillar capacitor PC, a fine hole pattern having a hexagonal close-packed arrangement is formed. At this time, how to reduce the pitch of the hole pattern is important. First, FIGS. 2A to 2C illustrate a schematic manufacturing method of the semiconductor device 1.

FIGS. 2A to 2C are schematic top views describing an outline of the method for manufacturing the semiconductor device 1 according to the embodiment. An object of the method for manufacturing the semiconductor device 1 according to the embodiment is to form a hole pattern having a hexagonal close-packed arrangement at a pitch finer than the limit resolution of lithography.

As illustrated in FIG. 2A, a resist mask pattern having a hexagonal close-packed arrangement is formed by using a lithography technique on a layer to be processed on which hole patterns are to be formed. At this time, the resist mask pattern is preferably formed at a pitch close to the limit resolution of lithography.

Thus, a resist mask pattern in which a hole pattern is arranged at each vertex of a regular hexagon and a center point of the regular hexagon is formed. FIG. 2A illustrates a regular hexagon in superposition with hole patterns taking a hexagonal close-packed arrangement.

The pitch between these hole patterns having the hexagonal close-packed arrangement is three times the pitch of the finally obtained hole patterns. An equilateral triangle illustrated in FIG. 2A is configured by a minimum distance connecting center points of hole patterns included in the resist mask pattern.

As illustrated in FIG. 2B, the hole patterns of FIG. 2A are transferred to a hard mask pattern. In addition, hole patterns are further formed between the transferred hole patterns. More specifically, an additional hole pattern is arranged at the center portion of the hole pattern overlapping each vertex of the equilateral triangle illustrated in FIG. 2A. At this time, the diameter of the hole patterns to be added is made smaller than the diameter of the hole patterns in FIG. 2A, and the diameter of the hole patterns in FIG. 2A is also reduced in accordance with the additional hole patterns.

Thus, in the hard mask pattern of FIG. 2B, the hole patterns have a pitch √3 that is times that of the finally obtained hole patterns. FIG. 2B illustrates a regular hexagon reduced from the regular hexagon illustrated in FIG. 2A in superposition with the hole patterns taking the hexagonal close-packed arrangement. In addition, the equilateral triangle configured by the minimum distance connecting the center points of the hole patterns in FIG. 2B and reduced from the equilateral triangle illustrated in FIG. 2A is illustrated.

As illustrated in FIG. 2C, a hole mask pattern of FIG. 2B is transferred to a hard mask layer different from the above to newly form a hard mask pattern, and an additional hole pattern is arranged at the center portion of the hole pattern overlapping each vertex of the equilateral triangle illustrated in FIG. 2B. In this way, by repeating the process illustrated in FIG. 2B again, final hole patterns having a desired pitch is obtained.

It can be seen that the regular hexagon overlapping the hole patterns of FIG. 2C taking the hexagonal close-packed arrangement is further reduced than the regular hexagon illustrated in FIGS. 2A and 2B. In addition, it can be seen that the equilateral triangle configured by the minimum distance connecting the center points of the hole patterns in FIG. 2C is further reduced than the equilateral triangle illustrated in FIGS. 2A and 2B.

As described above, by performing a process of forming a pattern of three times the pitch of the finally obtained hole patterns and reducing the pitch of the hole patterns to 1/√3 times twice, fine hole patterns of hexagonal close-packed arrangement having a pitch that is ⅓ times the pitch obtained with the limit resolution of lithography is formed by one lithography process.

Note that a process of forming an additional hole pattern at a center portion of the hole pattern overlapping each vertex of the equilateral triangle and reducing the pitch of the hole patterns to 1/√3 times is hereinafter also referred to as self-aligned triangle patterning (STP).

Hereinafter, a more detailed method for manufacturing the semiconductor device 1 according to the embodiment will be described.

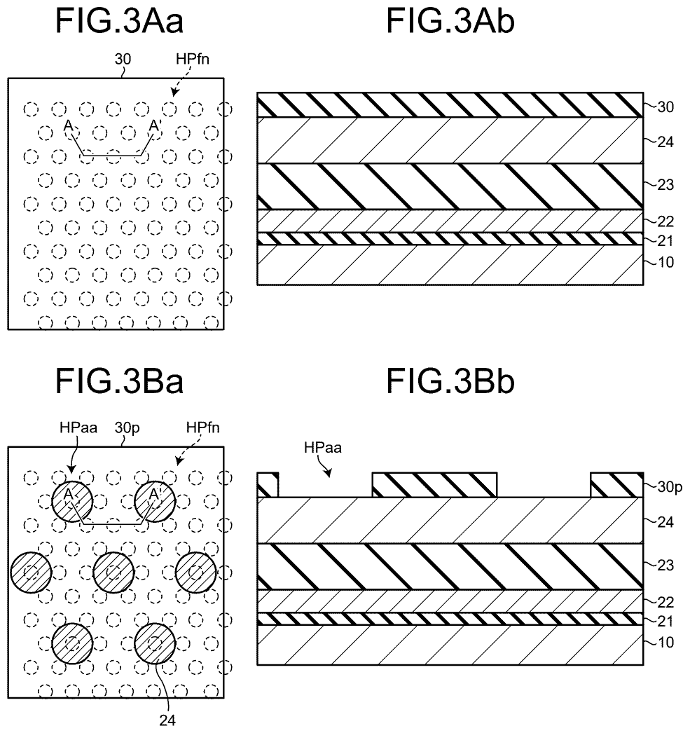

FIGS. 3Aa to 10Cb are views sequentially illustrating a part of the procedure of the method for manufacturing the semiconductor device 1 according to the embodiment. Aa to Ca in FIGS. 3Aa to 10Cb are top views of the semiconductor device 1 in the middle of manufacturing. Ab to Cb in FIGS. 3Aa to 10Cb are cross-sectional views taken along line A-A′ of Aa to Ca in FIGS. 3Aa to 10Cb of the semiconductor device 1 in the middle of manufacturing. Note that in Aa to Ca of FIGS. 3Aa to 10Cb, hole patterns finally obtained are indicated by broken lines.

As illustrated in FIG. 3Ab, a layer to be processed 10, four hard mask layers 21 to 24, and a resist mask layer 30 are formed in this order from the lower layer side.

The layer to be processed 10 is a layer to which final hole patterns HPfn illustrated in FIG. 3Aa are transferred, and the above-described pillar capacitor PC is formed. As the hard mask layers 21 to 24, a silicon layer, a silicon oxide layer, a silicon nitride layer, a silicon oxynitride layer, various metal layers, a metal oxide layer, or the like can be appropriately used.

As will be described later, since the layer to be processed 10 and the hard mask layers 21 to 24 are required to have selectivity for etching processing, it is preferable to use different materials for at least adjacent layers. Furthermore, as will be described later, layer thicknesses of the hard mask layers 21 to 24 affect the size and the like of the finally obtained hole patterns HPfn, and thus is preferably adjusted to appropriate layer thicknesses in advance.

For the resist mask layer 30, for example, a photoresist or the like is used.

It is assumed that the active region AA, the word line WL, and the bit line BL have been formed below the layer to be processed 10.

As illustrated in FIGS. 3Ba and 3Bb, a high-resolution lithography technique is used, and a resist mask pattern 30p having hole patterns HPaa with a pitch close to the limit resolution in the lithography technique is formed. As the high-resolution lithography technique, for example, immersion exposure using an ArF laser as a light source can be currently used. Thus, the lower hard mask layer 24 is exposed on bottom surfaces of the hole patterns HPaa.

As described above, the hole patterns HPaa formed in this manner are arranged in a hexagonal close-packed arrangement having a pitch three times the finally obtained hole patterns HPfn, for example. The resist mask pattern 30p having the hole patterns HPaa corresponds to the resist mask pattern having the hexagonal close-packed arrangement illustrated in FIG. 2A described above.

In addition, the hole patterns HPaa of the resist mask pattern 30p each have a larger diameter than that of the finally obtained hole patterns HPfn. As will be described later, the hole patterns HPaa of the resist mask pattern 30p are sequentially transferred to the hard mask layers 24 to 21, and at that time, the hole diameters of the hole patterns HPaa are also gradually reduced. As described above, the hole diameters of the hole patterns HPaa also affect the size or the like of the finally obtained hole patterns HPfn, and thus it is preferable that the hole diameters are adjusted to an appropriate size in advance.

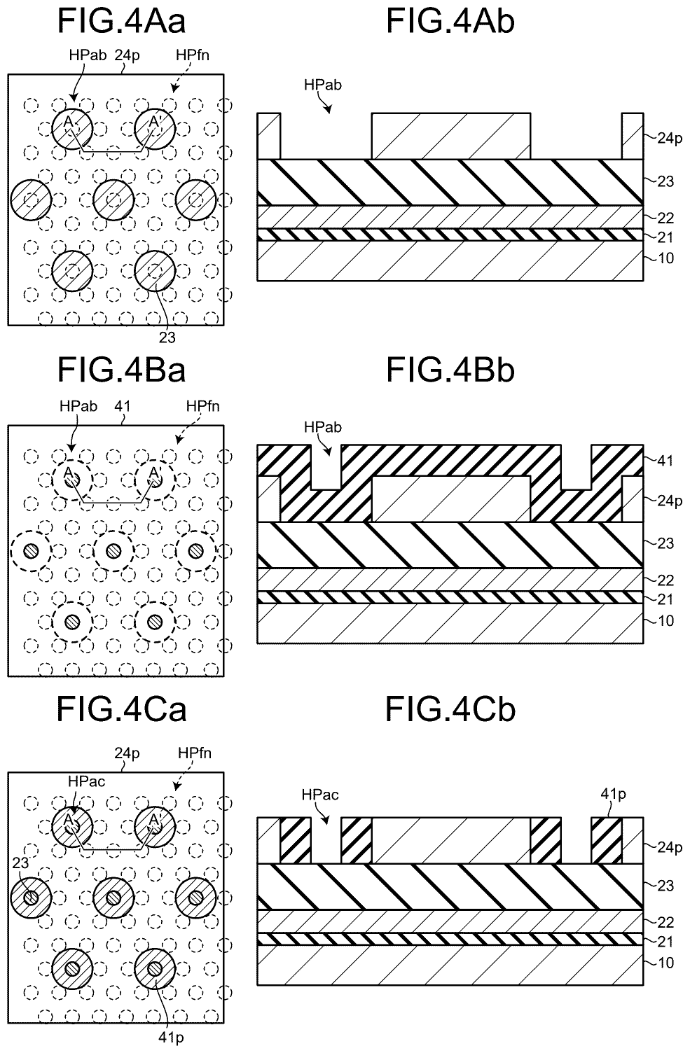

As illustrated in FIGS. 4Aa and 4Ab, the hole patterns HPaa of the resist mask pattern 30p are transferred to the hard mask layer 24 using reactive ion etching (RIE) or the like. Thus, a hard mask pattern 24p having hole patterns HPab is formed. In addition, the lower hard mask layer 23 is exposed from bottom surfaces of the hole patterns HPab.

Thereafter, the resist mask pattern 30p is removed by ashing using oxygen plasma or the like.

As illustrated in FIGS. 4Ba and 4Bb, a spacer layer 41 covering the hard mask pattern 24p is formed. The spacer layer 41 can also be formed by selecting and using a predetermined layer from the silicon layer, the silicon oxide layer, the silicon nitride layer, the silicon oxynitride layer, various metal layers, the metal oxide layer, and the like described above. Also in this case, for the spacer layer 41, it is preferred to use a material that provides selectivity with respect to the hard mask pattern 24p and the hard mask layer 23 exposed from the hard mask pattern 24p.

The spacer layer 41 covers an upper surface of the hard mask pattern 24p and side walls and bottom surfaces of the hole patterns HPab of the hard mask pattern 24p. At this time, the layer thickness of the spacer layer 41 is adjusted so that the hole patterns HPab are not completely filled. In addition, as described above, when the resist mask pattern 30p is initially formed, the hole size of the hole patterns HPaa is adjusted in advance, and the layer thickness of the hard mask layer 24 is adjusted.

In FIG. 4Ba, the interface between the hard mask pattern 24p covered with the spacer layer 41 and the spacer layer 41 is indicated by a broken line.

As illustrated in FIGS. 4Ca and 4Cb, the entire surface of the spacer layer 41 is etched back to remove the spacer layer 41 from the upper surface of the hard mask pattern 24p and an upper surface of the hard mask layer 23 exposed from the hole patterns HPab. Thus, hole patterns HPac having a spacer pattern 41p on a side wall are obtained. The lower hard mask layer 23 is exposed from bottom surfaces of the hole patterns HPac.

The hole patterns HPac have a diameter that is twice the thickness of the spacer pattern 41p and is smaller than that of the hole patterns HPab described above. However, the arrangement and pitch of the hole patterns HPac substantially coincide with those of the hole patterns HPab. That is, similarly to the hole patterns HPaa, HPab, and the like, the hole patterns HPac are arranged in a hexagonal close-packed arrangement having a pitch that is three times that of the finally obtained hole patterns HPfn.

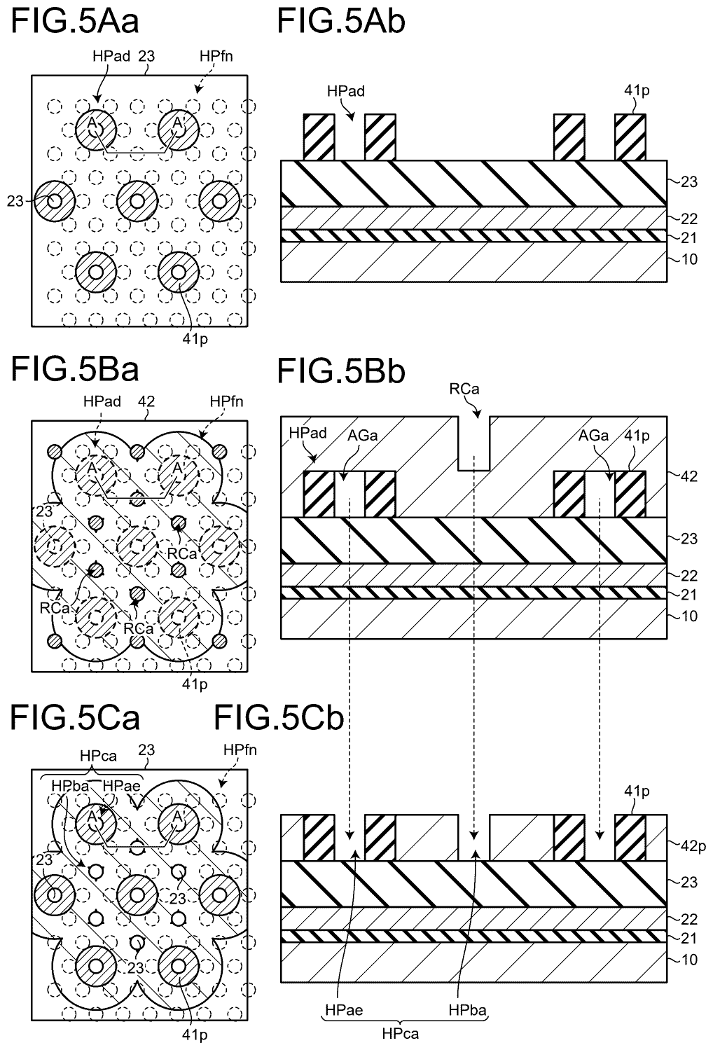

As illustrated in FIGS. 5Aa and 5Ab, the hard mask pattern 24p is removed by wet etching or the like. Thus, hole patterns HPad in which the spacer pattern 41p remains in a cylindrical shape on the hard mask layer 23 are obtained.

As illustrated in FIGS. 5Ba and 5Bb, the spacer pattern 41p and a spacer layer 42 that covers the hard mask layer 23 exposed from the spacer pattern 41p are formed. The spacer layer 42 can also be formed by selecting and using a predetermined layer from the silicon layer, the silicon oxide layer, the silicon nitride layer, the silicon oxynitride layer, various metal layers, the metal oxide layer, and the like described above. Also in this case, for the spacer layer 42, it is preferred to use a material capable of achieving selectivity with respect to the spacer pattern 41p and the hard mask layer 23.

The spacer layer 42 covers an upper surface of the spacer pattern 41p and the upper surface of the hard mask layer 23. At this time, formation conditions of the spacer layer 42 are controlled so that voids in the cylinders (holes) of the hole patterns HPad included in the spacer pattern 41p are maintained without being filled with the spacer layer 42. In addition, a layer thickness and an etch-back amount of the spacer layer 41, the hole size of the hole patterns HPaa in the resist mask pattern 30p, and the layer thickness of the hard mask layer 24 are adjusted in advance so that the inner diameter of the hole patterns HPad becomes sufficiently small. Thus, air gaps AGa whose upper portion is covered with the spacer layer 42 are formed in the cylinders (holes) of the hole patterns HPad.

Further, by forming the spacer layer 42 along the shapes of the hole patterns HPad protruding in a cylindrical shape, irregularities are formed on the surface of the spacer layer 42. Thus, a recess RCa is formed at each surface position of the spacer layer 42 corresponding to the center point of the equilateral triangle configured by the minimum distance connecting the center points of the hole patterns HPad having the hexagonal close-packed arrangement.

Note that, in FIG. 5Ba, the spacer pattern 41p and the hard mask layer 23 exposed on bottom surfaces of the air gaps AGa, which are portions covered with the spacer layer 42, are indicated by broken lines.

As illustrated in FIGS. 5Ca and 5Cb, the spacer layer 42 is entirely etched back to remove the spacer layer 42 from the upper surface of the spacer pattern 41p and the upper surface of the hard mask layer 23 exposed from the spacer pattern 41p. Thus, the air gaps AGa in the cylinder (hole) of the hole patterns HPad are exposed. In addition, substantially the entire hard mask layer 23 outside the hole patterns HPad is covered, and hole patterns HPae in which the air gaps AGa exposed again are used as hole portions are formed.

The hole patterns HPae have a pattern substantially identical to the above-described hole patterns HPac having the spacer pattern 41p on the side wall. That is, the hole patterns HPae have a configuration in which the hard mask pattern 24p portion of the hole patterns HPac described above is replaced with a spacer pattern 42p.

In addition, by the entire surface etch-back of the spacer layer 42, a hole pattern HPba is formed so that the recess RCa formed at the center point of the equilateral triangle configured by the minimum distance connecting the center points of the hole pattern HPad penetrates the spacer layer 42 and is mixed with the hole patterns HPae. More specifically, the hole pattern HPba is arranged at the center point of an equilateral triangle configured by the minimum distance connecting the center points of the hole patterns HPae having the hexagonal close-packed arrangement.

In this manner, the additional hole pattern HPba can be formed in a self-aligned manner with respect to the hole patterns HPae.

Thus, hole patterns HPca including the hole patterns HPae and the hole pattern HPba are arranged in a hexagonal close-packed arrangement having a pitch that is 1/√3 times that of the hole patterns HPaa included in the initial resist mask pattern 30p. In other words, the hole patterns HPca have a pitch that is √3 times that of the finally obtained hole patterns HPfn.

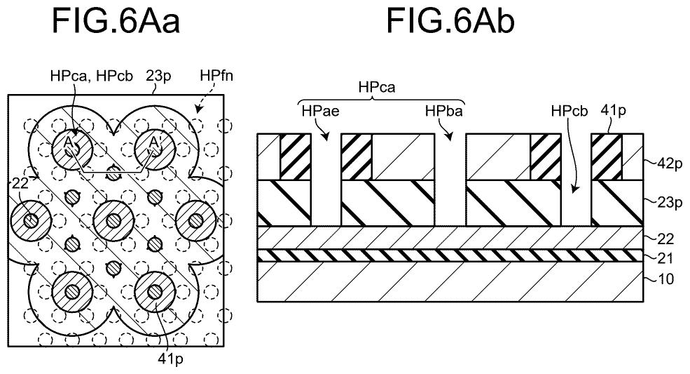

As illustrated in FIGS. 6Aa and 6Ab, the hole patterns HPca including the spacer patterns 41p and 42p are transferred to the hard mask layer 23 using, for example, RIE or the like. Thus, a hard mask pattern 23p having the hole patterns HPcb is formed. In addition, the lower hard mask layer 22 is exposed from bottom surfaces of the hole patterns HPcb.

The hard mask pattern 23p having the hole patterns HPcb corresponds to the hard mask pattern having the additional hole pattern illustrated in FIG. 2B described above. Thereafter, as described above with reference to FIGS. 2A to 2C, the processes in and after FIGS. 4Aa and 4Ab are repeated to further reduce the hole patterns HPcb by 1/√3 times.

Note that, in consideration of ease of understanding of the drawings, illustration of the spacer layer 42 and the configuration formed by the spacer layer 42 is partially omitted in the vicinity of end portions of four sides of the top views of FIGS. 5Ba, 5Ca, and 6Aa.

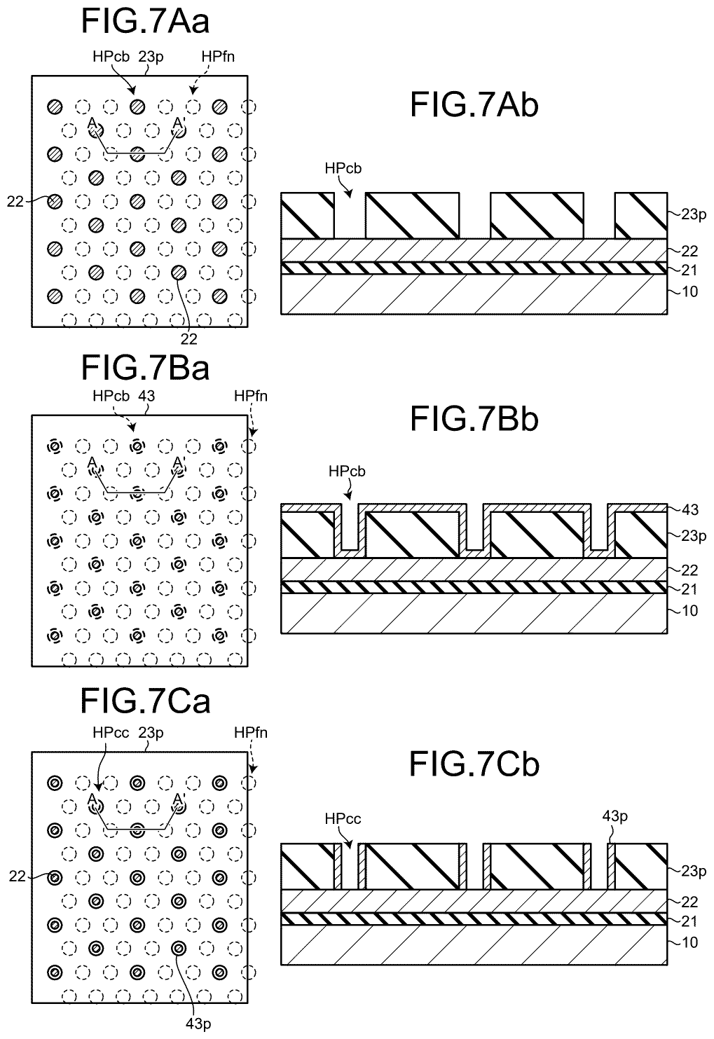

As illustrated in FIGS. 7Aa and 7Ab, the spacer patterns 41p and 42p are removed by wet etching or the like. Thus, the hard mask pattern 23p having the hole patterns HPcb is exposed.

As illustrated in FIGS. 7Ba and 7Bb, the spacer layer 43 covering the hard mask pattern 23p is formed. The spacer layer 43 can also be formed by selecting and using a predetermined layer from the silicon layer, the silicon oxide layer, the silicon nitride layer, the silicon oxynitride layer, various metal layers, the metal oxide layer, and the like described above. Also in this case, for the spacer layer 43, it is preferred to use a material that provides selectivity with respect to the hard mask pattern 23p and the hard mask layer 22 exposed from the hard mask pattern 23p.

The spacer layer 43 covers an upper surface of the hard mask pattern 23p and side walls and the bottom surfaces of the hole patterns HPcb included in the hard mask pattern 23p. At this time, the layer thickness of the spacer layer 43 is adjusted and the layer thickness of the hard mask layer 23 is adjusted in advance so that the hole patterns HPcb are not completely filled. In addition, the hole size of the hole patterns HPaa in the resist mask pattern 30p described above, the layer thickness of the hard mask layer 24, and the like are adjusted in consideration of processing of FIGS. 7Ba and 7Bb.

Note that, in FIG. 7Ba, an interface between the hard mask pattern 23p covered with the spacer layer 43 and the spacer layer 43 is indicated by a broken line.

As illustrated in FIGS. 7Ca and 7Cb, the entire surface of the spacer layer 43 is etched back to remove the spacer layer 43 from the upper surface of the hard mask pattern 23p and an upper surface of the hard mask layer 22 exposed from the hole patterns HPcb. Thus, hole patterns HPcc having a spacer pattern 43p on a side wall are obtained. The lower hard mask layer 22 is exposed from bottom surfaces of the hole patterns HPcc.

The hole patterns HPcc have a diameter that is twice the thickness of the spacer pattern 43p and is smaller than that of the hole patterns HPcb described above. However, the arrangement and pitch of the hole patterns HPcc substantially coincide with those of the hole patterns HPcb. That is, similarly to the hole patterns HPca, HPcb, and the like, the hole patterns HPcc are arranged in a hexagonal close-packed arrangement having a pitch that is √3 times that of the finally obtained hole patterns HPfn.

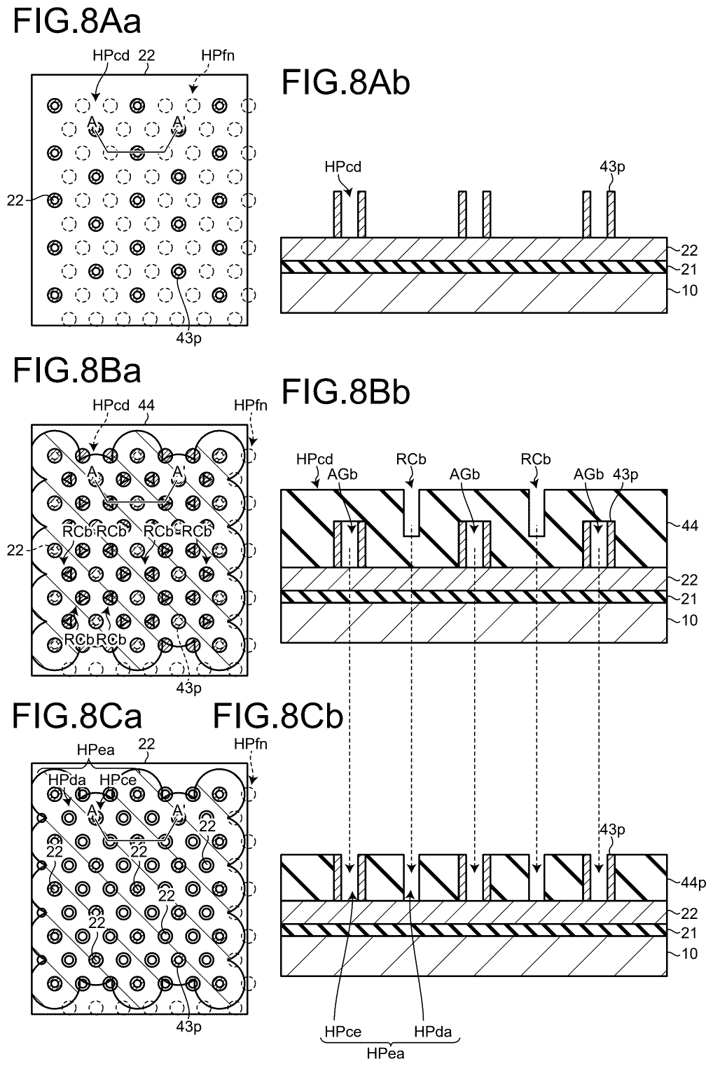

As illustrated in FIGS. 8Aa and 8Ab, the hard mask pattern 23p is removed by wet etching or the like. Thus, hole patterns HPcd in which the spacer pattern 43p remains in a cylindrical shape on the hard mask layer 22 is obtained.

As illustrated in FIGS. 8Ba and 8Bb, the spacer pattern 43p and a spacer layer 44 that covers the hard mask layer 22 exposed from the spacer pattern 43p are formed. The spacer layer 44 can also be formed by selecting and using a predetermined layer from the silicon layer, the silicon oxide layer, the silicon nitride layer, the silicon oxynitride layer, various metal layers, the metal oxide layer, and the like described above. Also in this case, for the spacer layer 44, it is preferred to use a material capable of achieving selectivity with respect to the spacer pattern 43p and the hard mask layer 22.

The spacer layer 44 covers an upper surface of the spacer pattern 43p and the upper surface of the hard mask layer 22. At this time, formation conditions of the spacer layer 44 are controlled so that voids in the cylinders (holes) of the hole patterns HPcd included in the spacer pattern 43p are maintained without being filled with the spacer layer 44. In addition, the layer thickness and the etch-back amount of the spacer layer 43 are adjusted in advance so that inner diameters of the hole patterns HPcd become sufficiently small. In addition, the hole size of the hole patterns HPaa in the resist mask pattern 30p, the layer thicknesses of the hard mask layers 23 and 24, and the like are adjusted in consideration of the processing of FIGS. 8Ba and 8Bb.

Thus, air gaps AGb whose upper portion is covered with the spacer layer 44 are formed in the cylinder (hole) of the hole patterns HPcd.

Further, by forming the spacer layer 44 along the shapes of the hole patterns HPcd protruding in a cylindrical shape, irregularities are formed on the surface of the spacer layer 44. Thus, a recess RCb is formed at each surface position of the spacer layer 44 corresponding to the center point of the equilateral triangle configured by the minimum distance connecting the center points of the hole patterns HPcd having the hexagonal close-packed arrangement.

Note that, in FIG. 8Ba, the spacer pattern 43p and the hard mask layer 22 exposed on bottom surfaces of the air gaps AGb, which are portions covered with the spacer layer 44, are indicated by broken lines.

As illustrated in FIGS. 8Ca and 8Cb, the spacer layer 44 is entirely etched back to remove the spacer layer 44 from the upper surface of the spacer pattern 43p and the upper surface of the hard mask layer 22 exposed from the spacer pattern 43p. Thus, the air gaps AGb in the cylinders (holes) of the hole patterns HPcd are exposed. In addition, substantially the entire hard mask layer 22 outside the hole patterns HPcd is covered, and hole patterns HPce in which the air gaps AGb exposed again are used as hole portions are formed.

The hole patterns HPce have a pattern substantially identical to the above-described hole patterns HPcc having the spacer pattern 43p on the side wall. That is, the hole patterns HPce have a configuration in which the hard mask pattern 23p portion of the hole patterns HPcc described above is replaced with a spacer pattern 44p.

In addition, by the entire surface etch-back of the spacer layer 44, a hole pattern HPda is formed so that the recess RCb formed at the center point of the equilateral triangle configured by the minimum distance connecting the center points of the hole patterns HPcd penetrates the spacer layer 44 and is mixed with the hole patterns HPce. More specifically, the hole pattern HPda is arranged at the center point of the equilateral triangle configured by the minimum distance connecting the center points of the hole patterns HPce having the hexagonal close-packed arrangement.

In this manner, the additional hole pattern HPda can be formed in a self-aligned manner with respect to the hole patterns HPce.

Thus, hole patterns HPea including the hole patterns HPce and the hole patterns HPda are arranged in a hexagonal close-packed arrangement having a pitch that is ⅓ times that of the hole patterns HPaa included in the original resist mask pattern 30p. In other words, with the hole patterns HPea, a pitch equivalent to that of the finally obtained hole patterns HPfn is obtained.

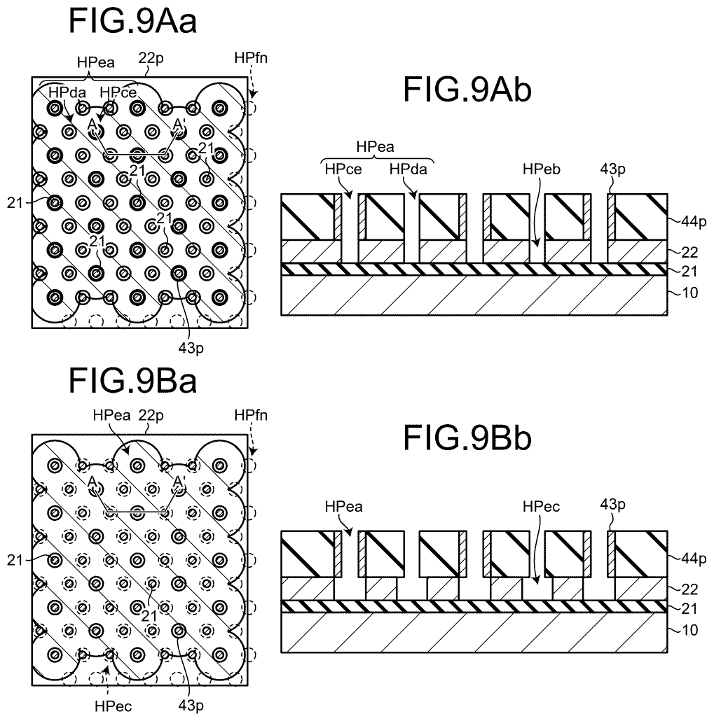

As illustrated in FIGS. 9Aa and 9Ab, the hole patterns HPea including the spacer patterns 43p and 44p are transferred to the hard mask layer 22 using, for example, RIE or the like. Thus, a hard mask pattern 22p having hole patterns HPeb is formed. Further, the lower hard mask layer 21 is exposed from bottom surfaces of the hole patterns HPeb.

The hard mask pattern 22p having the hole patterns HPeb corresponds to the hard mask pattern further having the additional hole pattern illustrated in FIG. 2C described above.

Note that, in consideration of ease of understanding of the drawings, illustration of the spacer layer 44 and the configuration formed by the spacer layer 44 is partially omitted in the vicinity of end portions of four sides of the top views of FIGS. 8Ba, 8Ca, and 9Aa.

As described above, the processing of repeating the processing of FIG. 4Aa and subsequent processing ends. That is, the processing of FIGS. 7Aa to 9Ab is repetition of the processing of FIGS. 4Aa to 6Ab.

The processing illustrated in FIGS. 9Ba and 9Bb is performed as necessary in order to finely adjust the size of the finally obtained hole pattern PCfn.

As illustrated in FIGS. 9Ba and 9Bb, wet etching or the like is performed on the hard mask pattern 22p on which the hole patterns HPeb is formed to expand the diameters of the hole patterns HPeb. Thus, hole patterns HPec in which the sizes of the hole patterns HPeb are finely adjusted are obtained. However, if a hole pattern having a desired size is obtained at the end of the processing of FIGS. 9Aa and 9Ab, the processing illustrated in FIGS. 9Ba and 9Bb can be skipped.

Note that, in FIG. 9Ba, hole patterns HCec of the hard mask pattern 22p covered with the spacer patterns 43p and 44p is indicated by a broken line.

In addition, during the process of forming the hole patterns HPeb on the hard mask pattern 22p in FIGS. 9Aa and 9Ab and the process of adjusting the sizes of the hole patterns HPeb in FIGS. 9Ba and 9Bb, the lowermost hard mask layer 21 functions as a protective layer that protects the layer to be processed 10.

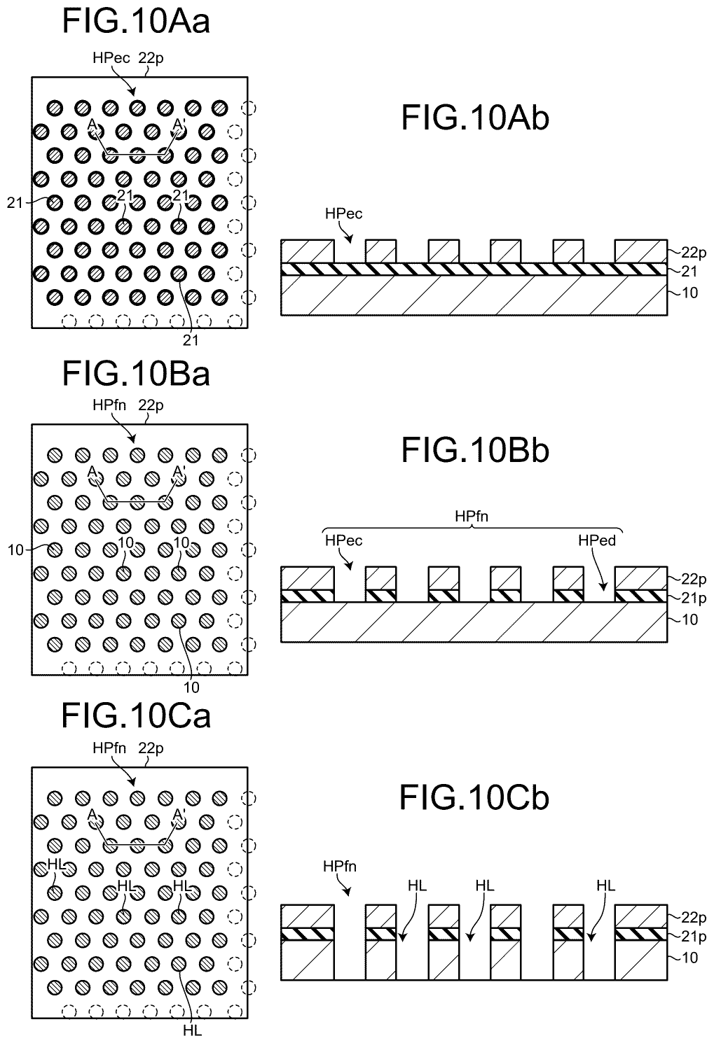

As illustrated in FIGS. 10Aa and 10Ab, the spacer patterns 41p and 42p are removed by wet etching or the like. Thus, the hard mask pattern 22p having the hole patterns HPec is exposed.

As illustrated in FIGS. 10Ba and 10Bb, the hole patterns HPec formed in the hard mask pattern 22p are transferred to the hard mask layer 21 using, for example, RIE or the like. Thus, a hard mask pattern 21p having the hole patterns HPed is formed. Further, the lower layer to be processed 10 is exposed from bottom surfaces of the hole patterns HPed.

Thereafter, as described below, the layer to be processed 10 is processed using the hard mask patterns 22p and 21p as masks. The hole patterns HPec and HPed included in the hard mask patterns 22p and 21p correspond to a finally obtained hole patterns HPfn.

As illustrated in FIGS. 10Ba and 10Bb, the layer to be processed 10 exposed from the hole patterns HPfn of the hard mask patterns 22p and 21p is processed using, for example, RIE or the like, so that a plurality of holes HL having a pitch that is ⅓ times that of the hole patterns HPaa of the original resist mask pattern 30p and having a hexagonal close-packed arrangement is formed in the layer to be processed 10.

Thereafter, a pillar capacitor PC is formed in each of the plurality of holes HL.

As described above, the semiconductor device 1 according to the embodiment is manufactured.

### (Overview)

For example, when a memory cell is formed in a semiconductor device such as a DRAM, a pillar capacitor having a hexagonal close-packed arrangement may be formed in order to increase a bit density per area. In the formation of the pillar capacitor in the hexagonal close-packed arrangement, hole patterns in the hexagonal close-packed arrangement is formed by lithography, for example. In recent years, there is an increasing demand for obtaining hole patterns having a pitch exceeding the limit resolution of lithography.

In order to form hole patterns at a pitch exceeding the limit resolution of lithography, cross-point processing of forming two types of L/S patterns obliquely with each other and forming hole patterns at intersection portions is used, or a side wall process used for forming a fine L/S pattern is applied to a circular pattern.

In the cross point processing, after a first type of L/S pattern is formed by lithography and transferred to a hard mask layer, a second type of L/S pattern formed by lithography is transferred to a hard mask layer newly formed on the hard mask layer so as to obliquely intersect the first type of L/S pattern at an angle of 60°. Thus, an overlapping portion of the patterns transferred to the two hard mask layers becomes, for example, a rhombic hole pattern in hexagonal close-packed arrangement.

In the cross point processing described above, an attempt has also been made to obtain finer hole patterns by combining side wall processes. That is, self-aligned double patterning (SADP) is used in which a spacer layer is formed on a side wall of a resist mask pattern having an L/S ratio of 1:3, and then the resist mask pattern is removed. Thus, an L/S pattern having a pitch that is ½ times that of a pattern obtained by lithography is obtained. Further, self-aligned quadrope patterning (SAQP) is performed twice by repeating the side wall machining twice, and an L/S pattern with a ¼ pitch may be used.

However, in order to obtain hole patterns of hexagonal close-packed arrangement by cross point processing using, for example, two-time side wall processing, a high-precision lithography process using a high-price device is performed twice, two-time side wall processing is further performed twice so as to process two hard mask layers, and thus the number of times of film formation and the number of etching processes are increased by substantially four times of side wall processing. Furthermore, in each process, high specifications are also required for dimensional variation accuracy and superimposition accuracy. Thus, the number of steps required to form the hole patterns, the turn around time (TAT), and the number of use devices increase, and it is difficult to suppress the manufacturing cost.

Furthermore, for example, in Patent Document 1 described above, the side wall process is applied to a circular pattern. That is, in the circular side wall processing of Patent Document 1, a hole pattern of hexagonal close-packed arrangement is formed by lithography, and a sacrificial layer is embedded in the hole pattern to form a pillar pattern by the sacrificial layer. By covering the pillar pattern with the spacer layer and then etching back, a new hole pattern is formed at the center point of an equilateral triangle formed by the minimum distance between the pillar patterns. Thereafter, by removing the sacrificial layer of the pillar pattern, hole patterns having a hexagonal close-packed arrangement having a pitch that is 1/√3 times the pitch of the hole patterns obtained in the original lithography are obtained.

However, in the circular side wall processing of Patent Document 1, it is necessary to form a sacrificial layer for obtaining a pillar pattern to be a core material of the spacer layer in addition to the formation of the spacer layer. This increases the number of steps required to form the hole patterns, the TAT, and the number of devices to be used, which leads to an increase in manufacturing cost.

According to the method for manufacturing the semiconductor device 1 of the embodiment, the spacer layer 42 covering the upper surface of the hard mask layer 23 outside the spacer pattern 41p is formed, and the spacer pattern 42p having the hole pattern HPba is formed by removing the spacer layer 42 overlapping the region configured by a minimum distance connecting center points of the spacer pattern 41p, thereby forming the hole patterns HPca including the hole patterns HPae configured by the spacer pattern 41p and the hole pattern HPba configured by the spacer pattern 42p.

Thus, a fine pattern exceeding the limit resolution of the lithography process can be formed.

According to the method for manufacturing the semiconductor device 1 of the embodiment, the spacer layer 44 covering the upper surface of the hard mask layer 22 outside the spacer pattern 43p is formed, and the spacer pattern 44p having the hole pattern HPda is formed by removing the spacer layer 44 overlapping the region formed by the minimum distance connecting the center points of the spacer pattern 43p, thereby forming the hole patterns HPea including the hole patterns HPce constituted by the spacer pattern 43p and the hole patterns HPda constituted by the spacer pattern 44p.

As described above, by repeating the pitch reduction process from FIGS. 4Aa to 6Ab and the pitch reduction process from FIGS. 7Aa to 9Ab a plurality of times, a finer pattern can be formed in one lithography process. Therefore, the number of lithography processes can be reduced, and dimensional variation accuracy and superposition accuracy can be easily ensured. Thus, the number of steps required to form the hole pattern, the TAT, and the number of use devices can be reduced, and the manufacturing cost can be reduced.

According to the method for manufacturing the semiconductor device 1 of the embodiment, the hole pattern HPaa is designed to have a hexagonal close-packed arrangement in which each pattern is arranged at each vertex of a regular hexagon and a center point of the regular hexagon when viewed from the stacking direction of the hard mask layers 21 to 25, and the hole pattern HPba is formed at the center point of a substantially equilateral triangular region configured by the minimum distance connecting the center points of the spacer patterns 41p.

Thus, hole patterns HPca having a pitch that is 1/√3 times that of the hole patterns HPaa initially formed by lithography can be obtained.

According to the method for manufacturing the semiconductor device 1 of the embodiment, the hole patterns HPea has a substantially hexagonal close-packed arrangement when viewed from the stacking direction of the hard mask layer 21 to 25. Thus, the hole patterns HPea having a pitch that is 1/√3 times that of the above-described hole pattern HPca and ⅓ times that of the original hole patterns HPaa can be obtained. In addition, by repeating the step of reducing to 1/√3 times pitch twice, the hole patterns HPfn having a pitch that is ⅓ times the initial pitch can be finally obtained in one lithography step.

According to the method of manufacturing the semiconductor device 1 of the embodiment, the spacer layer 42 covering the upper surface of the hard mask layer 23 outside the spacer pattern 41p and covering the upper surface of the spacer pattern 41p so as to form the air gaps AGa in the cylinders of the spacer patterns 41p is formed. Thus, unlike the circular side wall processing of Patent Document 1 described above, for example, the process of forming a pillar pattern using a sacrificial layer can be reduced.

Note that the pattern forming method of the above-described embodiment is applied to the formation of the pillar capacitor PC of the semiconductor device 1 configured as a DRAM. However, the pattern forming method of the above-described embodiment can also be appropriately applied when forming another configuration of the semiconductor device or a configuration of each unit of the semiconductor device other than the DRAM. In addition, the pattern forming method of the above-described embodiment may be applied to manufacturing of a template used for an imprinting process.

In addition, in the above-described embodiment, the reduction process to the 1/√3 times pitch is repeated a plurality of times, but even when the reduction process is performed once, the effect of the embodiment of forming a fine pattern exceeding the limit resolution of the lithography process can be obtained.

In the above embodiment, for example, in order to increase the density of the pillar capacitor PC as much as possible, the hole patterns are arranged in a hexagonal close-packed arrangement. However, the arrangement of the hole patterns is not limited to the hexagonal close-packed arrangement. As an example, the hole pattern can be arranged at each vertex of the regular square and the center point of the regular square. Such an arrangement of hole patterns is referred to as a cubic close-packed arrangement following the cubic close-packed structure of the crystal structure.

When the hole pattern in the cubic close-packed arrangement is formed, a hole pattern having a pitch of 1/√2 times the initial hole pattern can be obtained by newly adding a hole pattern to the center point of the equilateral triangle configured by the minimum distance connecting the center points of the hole patterns in the cubic close-packed arrangement formed by lithography. In addition, if this is repeated twice, hole patterns with a pitch that is ½ times that of the initial hole pattern is finally obtained.

### [Supplementary Note]

Hereinafter, preferred aspects of the present invention will be additionally described.

### (Supplementary Note 1)

According to one aspect of the present invention,
a method for manufacturing a semiconductor device is provided, the method including:
forming first and second hard mask layers above a layer to be processed in order of the second hard mask layer and the first hard mask layer from a side of the layer to be processed;
forming a resist mask pattern having a first hole pattern formed using lithography above the first hard mask layer;
transferring the first hole pattern to the first hard mask layer to form a first hard mask pattern having a second hole pattern;
forming a first spacer layer on a side wall of the second hole pattern and removing the first hard mask pattern to form a first spacer pattern being cylindrical and arranged at a position of the second hole pattern;
forming a second spacer layer covering an upper surface of the second hard mask layer outside the first spacer pattern, and removing the second spacer layer overlapping a first region consisting of a minimum distance connecting center points of the first spacer pattern to form a second spacer pattern having a third hole pattern, to form a fourth hole pattern including the first spacer pattern and the third hole pattern included in the second spacer pattern;
transferring the fourth hole pattern to the second hard mask layer to form a second hard mask pattern having a fifth hole pattern;
forming a third spacer layer on a side wall of the fifth hole pattern, and removing the second hard mask pattern to form a third spacer pattern being cylindrical and arranged at a position of the fifth hole pattern;
forming a fourth spacer layer covering an upper surface of the layer to be processed outside the third spacer pattern, and removing the fourth spacer layer overlapping a second region consisting of a minimum distance connecting center points of the third spacer pattern to form a fourth spacer pattern having a sixth hole pattern, to form a seventh hole pattern including the third spacer pattern and the sixth hole pattern included in the fourth spacer pattern; and
transferring the seventh hole pattern to the layer to be processed.

### (Supplementary Note 2)

According to another aspect of the present invention,
a method for manufacturing a semiconductor device is provided, the method including
forming a first hard mask layer above a layer to be processed;
forming a resist mask pattern having a first hole pattern formed using lithography above the first hard mask layer;
transferring the first hole pattern to the first hard mask layer to form a first hard mask pattern having a second hole pattern;
forming a first spacer layer on a side wall of the second hole pattern and removing the first hard mask pattern to form a first spacer pattern being cylindrical and arranged at a position of the second hole pattern;
forming a second spacer layer covering an upper surface of the layer to be processed outside the first spacer pattern, and covering an upper surface of the first spacer pattern so as to form a first air gap in a cylinder of the first spacer pattern;
removing the second spacer layer covering the upper surface of the first spacer pattern to open the second hole pattern again, and removing the second spacer layer overlapping a first region consisting of a minimum distance connecting center points of the first spacer pattern to form a second spacer pattern having a third hole pattern, to form a fourth hole pattern including the second hole pattern opened in the first spacer pattern and the third hole pattern opened in the second spacer pattern; and
transferring the fourth hole pattern to the layer to be processed.

### (Supplementary Note 3)

According to still another aspect of the present invention,
a pattern forming method is provided, the method including:
forming first and second hard mask layers in order of the second hard mask layer and the first hard mask layer from a side of a lower layer;
forming a resist mask pattern having a first hole pattern formed using lithography above the first hard mask layer;
transferring the first hole pattern to the first hard mask layer to form a first hard mask pattern having a second hole pattern;
forming a first spacer layer on a side wall of the second hole pattern and removing the first hard mask pattern to form a first spacer pattern being cylindrical and arranged at a position of the second hole pattern;
forming a second spacer layer covering an upper surface of the second hard mask layer outside the first spacer pattern, and removing the second spacer layer overlapping a first region consisting of a minimum distance connecting center points of the first spacer pattern to form a second spacer pattern having a third hole pattern, to form a fourth hole pattern including the first spacer pattern and the third hole pattern included in the second spacer pattern;
transferring the fourth hole pattern to the second hard mask layer to form a second hard mask pattern having a fifth hole pattern;
forming a third spacer layer on a side wall of the fifth hole pattern, and removing the second hard mask pattern to form a third spacer pattern being cylindrical and arranged at a position of the fifth hole pattern; and
forming a fourth spacer layer covering an outside of the third spacer pattern, and removing the fourth spacer layer overlapping a second region consisting of a minimum distance connecting center points of the third spacer pattern to form a fourth spacer pattern having a sixth hole pattern, to form a seventh hole pattern including the third spacer pattern and the sixth hole pattern included in the fourth spacer pattern.

### (Supplementary Note 4)

According to yet another aspect of the present invention,
a method for manufacturing a semiconductor device is provided, the method including:
forming a first hard mask layer above a layer to be processed;
forming a resist mask pattern having a first hole pattern formed using lithography above the first hard mask layer;
transferring the first hole pattern to the first hard mask layer to form a first hard mask pattern having a second hole pattern;
forming a first spacer layer on a side wall of the second hole pattern and removing the first hard mask pattern to form a first spacer pattern being cylindrical and arranged at a position of the second hole pattern;
forming a second spacer layer covering an upper surface of the layer to be processed outside the first spacer pattern, and removing the second spacer layer overlapping a first region consisting of a minimum distance connecting center points of the first spacer pattern to form a second spacer pattern having a third hole pattern, to form a fourth hole pattern including the first spacer pattern and the third hole pattern included in the second spacer pattern; and
transferring the fourth hole pattern to the layer to be processed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, the method comprising:
forming first and second hard mask layers above a layer to be processed in order of the second hard mask layer and the first hard mask layer from a side of the layer to be processed;
forming a resist mask pattern having a first hole pattern formed using lithography above the first hard mask layer;
transferring the first hole pattern to the first hard mask layer to form a first hard mask pattern having a second hole pattern;
forming a first spacer layer on a side wall of the second hole pattern and removing the first hard mask pattern to form a first spacer pattern being cylindrical and arranged at a position of the second hole pattern;
forming a second spacer layer at least covering an upper surface of the second hard mask layer outside the first spacer pattern, and partially removing the second spacer layer overlapping a first region consisting of a minimum distance connecting center points of the first spacer pattern to form a second spacer pattern having a third hole pattern, to form a fourth hole pattern including the first spacer pattern and the third hole pattern included in the second spacer pattern;
transferring the fourth hole pattern to the second hard mask layer to form a second hard mask pattern having a fifth hole pattern;
forming a third spacer layer on a side wall of the fifth hole pattern, and removing the second hard mask pattern to form a third spacer pattern being cylindrical and arranged at a position of the fifth hole pattern;
forming a fourth spacer layer at least covering an upper surface of the layer to be processed outside the third spacer pattern, and partially removing the fourth spacer layer overlapping a second region consisting of a minimum distance connecting center points of the third spacer pattern to form a fourth spacer pattern having a sixth hole pattern, to form a seventh hole pattern including the third spacer pattern and the sixth hole pattern included in the fourth spacer pattern; and
transferring the seventh hole pattern to the layer to be processed.

2. The method for manufacturing a semiconductor device according to claim 1, wherein
the first hole pattern is formed to be a hexagonal close-packed arrangement in which each of the patterns is arranged at each of vertexes of a regular hexagon and a center point of the regular hexagon when viewed from a stacking direction of the first and second hard mask layers.

3. The method for manufacturing a semiconductor device according to claim 2, wherein
the first region has a shape of a substantially equilateral triangle when viewed from the stacking direction, and
the third hole pattern is substantially formed at a center point of the first region.

4. The method for manufacturing a semiconductor device according to claim 2, wherein
the fourth hole pattern substantially has the hexagonal close-packed arrangement when viewed from the stacking direction.

5. The method for manufacturing a semiconductor device according to claim 4, wherein
the fourth hole pattern has a pitch that is substantially 1/√3 times a pitch of the first hole pattern.

6. The method for manufacturing a semiconductor device according to claim 4, wherein
the second region has a shape of a substantially equilateral triangle when viewed from the stacking direction, and
the sixth hole pattern is substantially formed at a center point of the second region.

7. The method for manufacturing a semiconductor device according to claim 2,
the seventh hole pattern substantially has the hexagonal close-packed arrangement when viewed from the stacking direction.

8. The method for manufacturing a semiconductor device according to claim 7,
the seventh hole pattern has a pitch that is substantially ⅓ times a pitch of the first hole pattern.

9. The method for manufacturing a semiconductor device according to claim 1, wherein
the second spacer layer is formed, while covering the upper surface of the second hard mask layer, to cover an upper surface of the first spacer pattern so as to form a first air gap in a cylinder of the first spacer pattern, and
the second spacer pattern is formed by removing the second spacer layer overlapping with the first region, and removing the second spacer layer covering the upper surface of the first spacer pattern.

10. The method for manufacturing a semiconductor device according to claim 1, wherein
the fourth spacer layer is formed, while covering the upper surface of the layer to be processed, to cover an upper surface of the third spacer pattern so as to form a second air gap in a cylinder of the third spacer pattern, and
the fourth spacer pattern is formed by removing the fourth spacer layer overlapping the second region, and removing the fourth spacer layer covering the upper surface of the third spacer pattern.

11. A method for manufacturing a semiconductor device, the method comprising:
forming a first hard mask layer above a layer to be processed;
forming a resist mask pattern having a first hole pattern formed using lithography above the first hard mask layer;
transferring the first hole pattern to the first hard mask layer to form a first hard mask pattern having a second hole pattern;
forming a first spacer layer on a side wall of the second hole pattern and removing the first hard mask pattern to form a first spacer pattern being cylindrical and arranged at a position of the second hole pattern;
forming a second spacer layer covering an upper surface of the layer to be processed outside the first spacer pattern, and covering an upper surface of the first spacer pattern so as to form a first air gap in a cylinder of the first spacer pattern;
removing the second spacer layer covering the upper surface of the first spacer pattern to open the second hole pattern again, and removing the second spacer layer overlapping a first region consisting of a minimum distance connecting center points of the first spacer pattern to form a second spacer pattern having a third hole pattern, to form a fourth hole pattern including the second hole pattern opened in the first spacer pattern and the third hole pattern opened in the second spacer pattern; and
transferring the fourth hole pattern to the layer to be processed.

12. The method for manufacturing a semiconductor device according to claim 11, wherein
the first hole pattern is formed to be a hexagonal close-packed arrangement in which each of the patterns is arranged at each of vertexes of a regular hexagon and a center point of the regular hexagon when viewed from a stacking direction of the layer to be processed and the first hard mask layer.

13. The method for manufacturing a semiconductor device according to claim 12, wherein
the first region has a shape of a substantially equilateral triangle when viewed from the stacking direction, and
the third hole pattern is substantially formed at a center point of the first region.

14. The method for manufacturing a semiconductor device according to claim 12, wherein
the fourth hole pattern substantially has the hexagonal close-packed arrangement when viewed from the stacking direction.

15. The method for manufacturing a semiconductor device according to claim 14, wherein
the fourth hole pattern has a pitch that is substantially 1/√3 times a pitch of the first hole pattern.

16. The method for manufacturing a semiconductor device according to claim 11, wherein
when the first hard mask layer is formed,
the first hard mask layer is formed by interposing a second hard mask layer between the first hard mask layer and the layer to be processed, and
when the fourth hole pattern is transferred to the layer to be processed,
the fourth hole pattern is transferred to the second hard mask layer to form a second hard mask pattern having a fifth hole pattern,
a third spacer layer is formed on a side wall of the fifth hole pattern and removing the second hard mask pattern to form a third spacer pattern being cylindrical and arranged at a position of the fifth hole pattern,
a fourth spacer layer is formed covering the upper surface of the layer to be processed outside the third spacer pattern, and covering an upper surface of the third spacer pattern so as to form a second air gap in a cylinder of the third spacer pattern,
the fourth spacer layer covering the upper surface of the third spacer pattern is removed to open the fifth hole pattern again and the fourth spacer layer overlapping a second region consisting of a minimum distance connecting center points of the third spacer pattern is removed to form a fourth spacer pattern having a sixth hole pattern, to form a seventh hole pattern including the fifth hole pattern opened in the third spacer pattern and the sixth hole pattern opened in the fourth spacer pattern, and
the fourth hole pattern is transferred to the layer to be processed via the second hard mask layer by transferring the seventh hole pattern to the layer to be processed.

17. The method for manufacturing a semiconductor device according to claim 16, wherein
the first hole pattern is formed to be a hexagonal close-packed arrangement in which each of the patterns is arranged at each of vertexes of a regular hexagon and a center point of the regular hexagon when viewed from a stacking direction of the first and second hard mask layers, and
the fourth hole pattern substantially has the hexagonal close-packed arrangement when viewed from the stacking direction.

18. The method for manufacturing a semiconductor device according to claim 17, wherein
the seventh hole pattern substantially has the hexagonal close-packed arrangement when viewed from the stacking direction.

19. The method for manufacturing a semiconductor device according to claim 18, wherein
the seventh hole pattern has a pitch that is substantially ⅓ times a pitch of the first hole pattern.

20. A pattern forming method comprising:
forming first and second hard mask layers in order of the second hard mask layer and the first hard mask layer from a side of a lower layer;
forming a resist mask pattern having a first hole pattern formed using lithography above the first hard mask layer;
transferring the first hole pattern to the first hard mask layer to form a first hard mask pattern having a second hole pattern;
forming a first spacer layer on a side wall of the second hole pattern and removing the first hard mask pattern to form a first spacer pattern being cylindrical and arranged at a position of the second hole pattern;
forming a second spacer layer covering an upper surface of the second hard mask layer outside the first spacer pattern, and removing the second spacer layer overlapping a first region consisting of a minimum distance connecting center points of the first spacer pattern to form a second spacer pattern having a third hole pattern, to form a fourth hole pattern including the first spacer pattern and the third hole pattern included in the second spacer pattern;
transferring the fourth hole pattern to the second hard mask layer to form a second hard mask pattern having a fifth hole pattern;
forming a third spacer layer on a side wall of the fifth hole pattern, and removing the second hard mask pattern to form a third spacer pattern being cylindrical and arranged at a position of the fifth hole pattern; and
forming a fourth spacer layer covering an outside of the third spacer pattern, and removing the fourth spacer layer overlapping a second region consisting of a minimum distance connecting center points of the third spacer pattern to form a fourth spacer pattern having a sixth hole pattern, to form a seventh hole pattern including the third spacer pattern and the sixth hole pattern included in the fourth spacer pattern.
